(19) United States
(12) Patent Application Publication
(10) Pub. No.: US 2009/0102063 A1
(43) Pub. Date: Apr. 23, 2009

(54) Semiconductor package and method for fabricating the same

(75) Inventors: Chun-Yuan Lee, Taichung Hsien (TW); Chien Ping Huang, Taichung (TW); Yu-Ting Lai, Taichung Hsien (TW); Cheng-Hsu Hsiao, Taichung Hsien (TW); Chun-Chi Ke, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 12/287,936

(22) Filed: Oct. 14, 2008

(30) Foreign Application Priority Data
Oct. 22, 2007 (TW) 096139467

(51) Int. Cl. H01L 23/48; H01L 21/00

(52) U.S. Cl. 257/778; 438/124; 257/E23.039

(57) ABSTRACT

This invention provides a semiconductor package and a method for fabricating the same. The method includes: forming a first resist layer on a metal carrier; forming a plurality of openings penetrating the first resist layer; forming a conductive metal layer in the openings; removing the first resist layer; covering the metal carrier having the conductive metal layer with a dielectric layer; forming blind vias in the dielectric layer to expose a portion of the conductive metal layer; forming conductive circuit on the dielectric layer and conductive posts in the blind vias, such that the conductive circuit is electrically connected to the conductive metal layer via the conductive posts; electrically connecting at least one chip to the conductive circuit; forming an encapsulant for encapsulating the chip and the conductive circuit; and removing the metal carrier, thereby allowing a semiconductor package to be formed without a chip carrier. Given the conductive posts, both the conductive circuit and conductive metal layer are efficiently coupled to the dielectric layer to prevent delamination. Further, downsizing the blind vias facilitates the fabrication process and cuts the fabrication cost.

### BACKGROUND OF THE INVENTION

1. Field of the Invention

The present invention relates generally to a semiconductor package and method for fabricating the same, and more particularly to a semiconductor package without chip carrier and method for fabricating the same.

2. Description of Related Art

In a conventional semiconductor package, a lead frame is used as a chip carrier, which comprises a die pad and a plurality of leads formed around periphery of the die pad. A semiconductor chip is adhered to the die pad and electrically connected with the leads by bonding wires, and further, the chip, the die pad, the bonding wires and inner side of the leads are encapsulated by a package resin so as to form a semiconductor package with lead frame.

There are various kinds of semiconductor packages with lead frame. For example, a QFP (Quad Flat Package) semiconductor package uses outer leads for electrical connection with an external device while a QFN (Quad Flat Non-leaded) semiconductor package eliminates outer leads so as to reduce the package size.

However, limited by thickness of the conventional lead frames, height of the semiconductor packages cannot be further reduced, which accordingly cannot meet demands for lighter, thinner, shorter and smaller semiconductor products. Therefore, semiconductor packages without chip carrier are developed, which have reduced height and become much thinner compared with the conventional semiconductor packages with lead frame.

Referring to FIGS. 1A to 1E, U.S. Pat. No. 6,884,652 discloses a method for fabricating a semiconductor package without chip carrier. First, as shown in FIG. 1A, a copper plate 10 is provided, a dielectric layer 11 made of such as PP (Prepeg) or ABF (Ajinomoto Build-up Film) is formed on the copper plate 10, and a plurality of openings 110 is formed in the dielectric layer 11 at predefined positions such that a solder material 12 can be formed in the openings 110 of the dielectric layer 11 by electroplating. Then, a first thin copper layer 13 is formed on the dielectric layer 11 and the solder material 12 by electroless plating or sputtering, as shown in FIG. 1B. Subsequently, a second copper layer 14 is formed on the first thin copper layer 13 by electroplating, and the first thin copper layer 13 and the second copper layer 14 are patterned to form a plurality of conductive circuits. Each of the conductive circuits has a terminal 141 and a metal layer 15 is formed on the terminals 141 by electroplating, as shown in FIG. 1C. Subsequently, at least a chip 16 is mounted to predefined position of the conductive circuits and electrically connected to the terminals 141 having the metal layer 15 through a plurality of bonding wires 17, and an encapsulant 18 is formed to encapsulate the chip 16 and the bonding wires 17, as shown in FIG. 1D. Finally, the copper plate 10 is removed by etching so as to expose the dielectric layer 11 and the solder material 12, as shown in FIG. 1E.

However, in the above-described method, as positions of the terminals (solder material 12) for electrically connecting the chip 16 with an external device are defined by the openings 110 of the dielectric layer 11, the openings 110 must have a predefined large size (for example 400 μm). Meanwhile, since the dielectric layer made of PP or ABF is not a photosensitive material, the openings 110 cannot be formed through a photolithography process. Instead, the openings 110 are conventionally formed by laser ablation. As a result, both the fabrication time and cost are increased.

Further, as the conductive circuits only have a thickness of 5-10 μm and have a poor bonding with the encapsulant, delimination can easily occur between the terminals of the conductive circuits and the encapsulant.

Therefore, how to provide a semiconductor package without chip carrier and a method for fabricating the same so as to avoid the above drawbacks has become urgent.

### SUMMARY OF THE INVENTION

According to the above drawbacks, an objective of the present invention is to provide a semiconductor package without chip carrier and a method for fabricating the same, which overcomes the conventional drawbacks of complicated fabrication process and high cost caused by large-sized openings formed in the dielectric layer.

Another objective of the present invention is to provide a semiconductor package and method for fabricating the same, wherein conductive circuit can be embedded in the dielectric layer so as to overcome the conventional delamination problem.

In order to attain the above and other objectives, the present invention discloses a method for fabricating a semiconductor package, which comprises the step of: forming a first resist layer on a metal carrier and forming a plurality of openings in the first resist layer at predefined positions to expose the metal carrier; forming a conductive metal layer in the openings; removing the first resist layer, forming a dielectric layer to cover one side of the metal carrier having the conductive metal layer, and forming a plurality of blind vias in the dielectric layer to expose part of the conductive metal layer; forming conductive circuit on the dielectric layer and forming conductive posts in the blind vias, wherein the conductive circuit is electrically connected to the conductive metal layer through the conductive posts; electrically connecting at least one chip to the conductive circuit; forming an encapsulant to encapsulate the chip and the conductive circuit; and removing the metal carrier so as to expose the dielectric layer and the conductive metal layer.

Method for fabricating the conductive circuit and conductive posts comprising: forming a conductive layer on the dielectric layer and the conductive metal layer exposed from the blind vias through electroless plating; forming a second resist layer to cover the conductive layer and forming a plurality of patterned openings in the second resist layer; performing an electroplating process to form conductive circuit on the conductive layer exposed from the openings and conductive posts in the blind vias, the conductive circuit being electrically connected to the conductive metal layer through the conductive posts; and removing the second resist layer and the conductive layer covered by the second resist layer.

Through the above described fabrication method, a semiconductor package is obtained, which comprises: a conductive metal layer; a dielectric layer covering one side of the conductive metal layer, wherein the dielectric layer has blind vias formed to expose part of the conductive metal layer; conductive circuit formed on the dielectric layer; conductive posts formed in the blind vias for electrically connecting the conductive circuit with the conductive metal layer; a chip electrically connected with the conductive circuit; and an encapsulant encapsulating the chip and the conductive circuit. In addition, a conductive layer is formed between the conductive circuit and the dielectric layer as well as between the conductive posts and the blind vias.

Further, conductive elements such as solder balls can be mounted to the exposed conductive metal layer so as to electrically connect the chip to an external device.

Furthermore, before the conductive metal layer is formed, an electroplating layer made of a same material as the metal carrier can be formed in the openings of the first resist layer such that when the metal carrier is removed, the electroplating layer can be removed at the same time, thereby making surface of the conductive metal layer be lower than that of the dielectric layer. Thus, the conductive elements can be efficiently mounted to the conductive metal layer.

Moreover, an insulative layer such as a solder mask layer can be formed to cover the conductive circuit, and openings are formed in the insulative layer to expose part of the conductive circuit such that the chip can be flip-chip electrically connected to the conductive circuit.

Furthermore, the conductive metal layer can be made of a same material as the metal carrier, such that when the metal carrier is removed, part of the conductive metal layer can be removed at the same time, and by controlling the etch quantity of the conductive metal layer, surface of the conductive metal layer can be lower than that of the dielectric layer, thereby allowing the conductive elements to be efficiently mounted to the conductive metal layer.

Therefore, the present invention mainly comprises forming a first resist layer on a metal carrier and forming a plurality of openings in the first resist layer to expose the metal carrier such that a conductive metal layer can be formed in the openings; removing the first resist layer, forming a dielectric layer to cover one side of the metal carrier having the conductive metal layer, and forming a plurality of blind vias in the dielectric layer to expose part of the conductive metal layer; forming conductive circuit on the dielectric layer and forming conductive posts in the blind vias, wherein the conductive circuit is electrically connected with the conductive metal layer through the conductive posts; electrically connecting at least one chip to the conductive circuit; forming an encapsulant encapsulating the chip and the conductive circuit and removing the metal carrier so as to expose the dielectric layer and the conductive metal layer functioning as electrical connection terminals. Thus, a semiconductor package without chip carrier is obtained. Since the conductive circuit and the conductive metal layer functioning as electrical connection terminals are efficiently embedded in the dielectric layer through the conductive posts, the conventional delamination problem is avoided. Further, the blind vias formed in the dielectric layer have small size, thereby facilitating the fabrication process and saving the fabrication cost compared with the large-sized openings in the prior art.

### BRIEF DESCRIPTION OF DRAWINGS

FIGS. 1A to 1E are sectional diagrams showing a semiconductor package without chip carrier disclosed by U.S. Pat. No. 6,884,652;

FIGS. 2A to 2H are sectional diagrams showing a semiconductor package and method for fabricating the same according to a first embodiment of the present invention;

FIGS. 3A to 3C are sectional diagrams showing a semiconductor package and method for fabricating the same according to a second embodiment of the present invention;

FIGS. 4A and 4B are sectional diagrams showing a semiconductor package and method for fabricating the same according to a third embodiment of the present invention; and

FIG. 5 is a sectional diagram showing a semiconductor package and method for fabricating the same according to a fourth embodiment of the present invention.

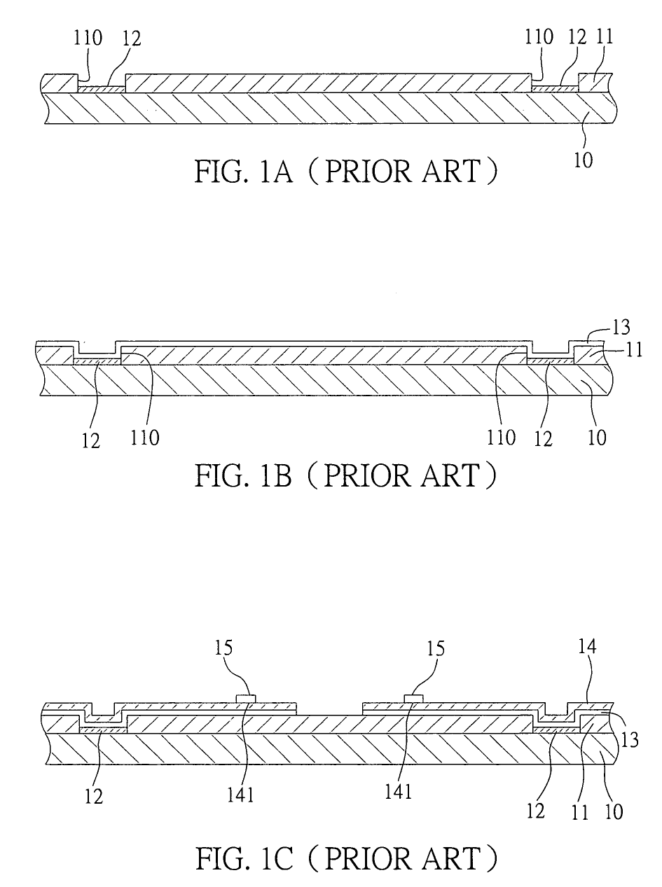

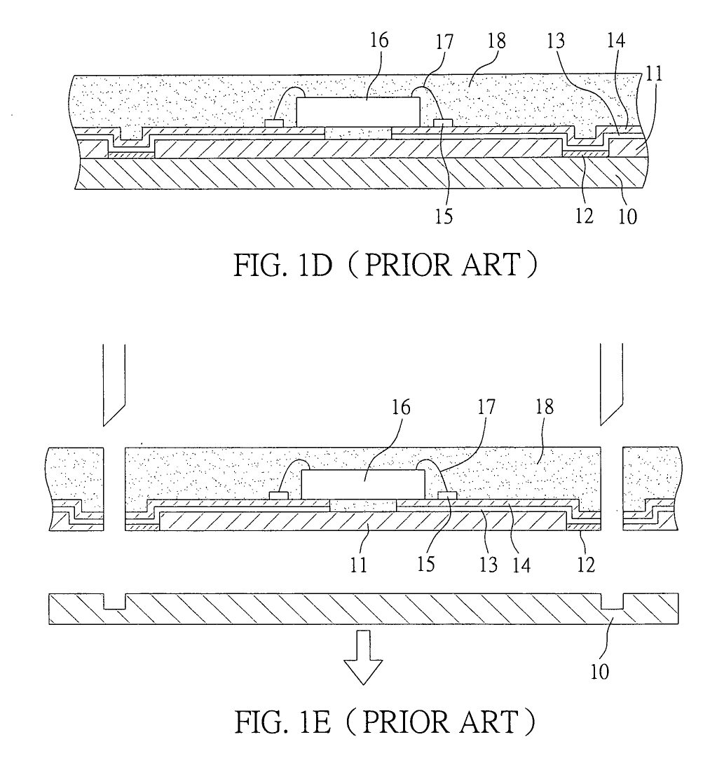

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification.

### First Embodiment

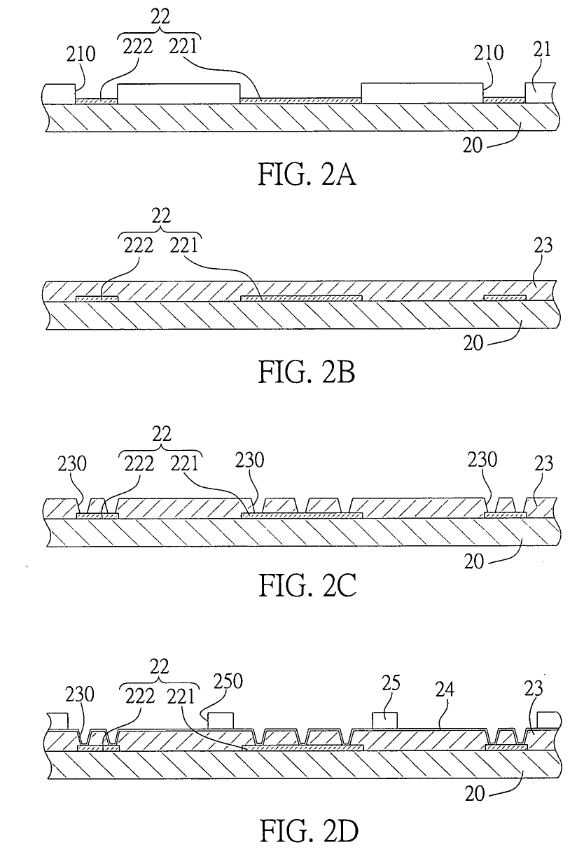

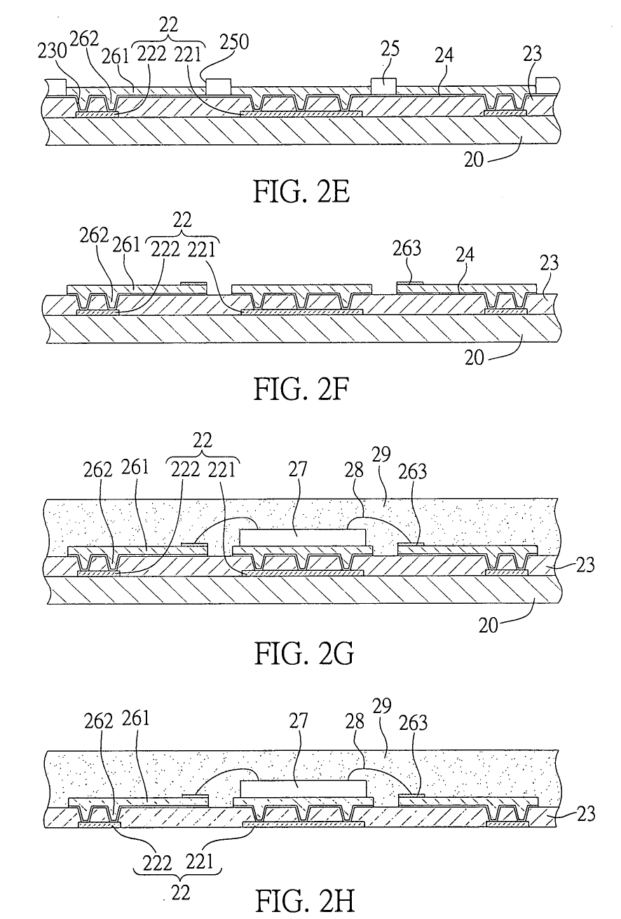

FIGS. 2A to 2H are sectional diagrams showing a semiconductor package and a method for fabricating the same according to a first embodiment of the present invention.

As shown in FIG. 2A, a metal carrier 20 such as a copper plate is prepared, a first resist layer 21 such as photo-resist is formed on one surface of the metal carrier 20, and a plurality of openings 210 penetrating the first resist layer 21 is formed by exposure and development so as to expose part of the metal carrier 20.

Subsequently, a conductive metal layer 22 is formed in the openings 210 of the first resist layer 21, wherein the conductive metal layer 22 comprises a die pad 221 corresponding to a chip position and electrical connection terminals 222 for electrically connecting the chip with an external device. The conductive metal layer 22 can be made of such as Au/Ni/Cu, Ni/Cu, Au/Ni/Au, Au/Ni/Pd/Au, Au/Pd/Ni/Pd and so on.

As shown in FIGS. 2B and 2C, the first resist layer 21 is removed, a dielectric layer 23 made of such as PP or ABF is formed on surface of the metal carrier 20 having the conductive metal layer 22, and a plurality of blind vias 230 is formed in the dielectric layer 23 by such as laser processing so as to expose part of the conductive metal layer 22. Therein, the blind vias 230 have a diameter of about 100 μm, which is greatly smaller than conventional openings of 400 μm formed in the dielectric layer, thereby facilitating the fabrication process and saving the fabrication cost.

As shown in FIGS. 2D and 2E, a conductive layer 24 such as a thin copper layer is formed on the dielectric layer 23 and the conductive metal layer 22 exposed from the blind vias 230 through such as an electroless plating, and then a second resist layer 25 such as dry film is formed to cover the conductive layer 24. Through exposure and development process, a plurality of patterned openings 250 is formed.

Thereafter, conductive circuit 261 is formed on the conductive layer 24 in the openings 250 and conductive posts 262 are formed in the blind vias 230 such that the conductive circuit 261 can be electrically connected to the conductive metal layer 22 through the conductive posts 262.

Thus, the conductive circuit 261 and the conductive metal layer 22 functioning as electrical connection terminals 222 are efficiently embedded in the dielectric layer 23 through the conductive posts 262, thereby avoiding the conventional delamination problem.

As shown in FIG. 2F, the second resist layer 25 and the conductive layer 24 covered by the second resist layer 25 are removed. In addition, solder material 263 made of such as Ni/Au is formed on terminals of the conductive circuit 261.

As shown FIGS. 2G and 2H, at least one chip 27 is mounted on the conductive circuit 261 at position corresponding to the die pad 221 of the conductive metal layer 22 and electrically connected to the solder material 263 on the terminals of the conductive circuit 261 by bonding wires 28.

Subsequently, an encapsulant 29 is formed to encapsulate the chip 27 and the conductive circuit 261. The metal carrier 20 is removed so as to expose the dielectric layer 23 and the conductive metal layer 22. Thereafter, the chip can be electrically connected to an external device through the exposed conductive metal layer 22 functioning as the electrical connection terminals.

According to the above fabrication method, the present invention further discloses a semiconductor package, which comprises: a conductive metal layer 22; a dielectric layer 23 covering the conductive metal layer 22 and having blind vias 230 formed to expose part of the conductive metal layer 22; conductive circuit 261 formed on the dielectric layer 23; conductive posts 262 formed in the blind vias 230 such that the conductive circuit 261 can be electrically connected to the conductive metal layer 22 through the conductive posts 262; a chip 27 electrically connected to the conductive circuit 261; and an encapsulant 29 encapsulating the chip 27 and the conductive circuit 261.

Further, between the conductive circuit 261 and the dielectric layer 23 as well as between the conductive posts 262 and the blind vias 230 there is formed a conductive layer 24.

The conductive metal layer 22 comprises a die pad 221 corresponding to the chip position and electrical connection terminals 222 for electrically connecting the chip 27 with an external device.

According to the present invention, a first resist layer is formed on a metal carrier and a plurality of openings is formed in the first resist layer to expose the metal carrier such that a conductive metal layer can be formed in the openings. Subsequently, the first resist layer is removed and a dielectric layer is formed on the metal carrier having the conductive metal layer. A plurality of blind vias is formed in the dielectric layer to expose part of the conductive metal layer. Then, conductive circuit is formed on the dielectric layer and conductive posts are formed in the blind vias, wherein the conductive circuit is electrically connected with the conductive metal layer through the conductive posts. Since the conductive circuit and the conductive metal layer functioning as electrical connection terminals are efficiently embedded in the dielectric layer through the conductive posts, the conventional delamination problem is avoided. Further, the blind vias formed in the dielectric layer have small size, thereby facilitating the fabrication process and saving the fabrication cost compared with the large-sized openings in the prior art. Further, at least one chip is electrically connected to the conductive circuit and an encapsulant encapsulating the chip and the conductive circuit is formed, and the metal carrier is removed so as to expose the dielectric layer and the conductive metal layer functioning as electrical connection terminals. Thus, a semiconductor package without chip carrier is obtained.

### Second Embodiment

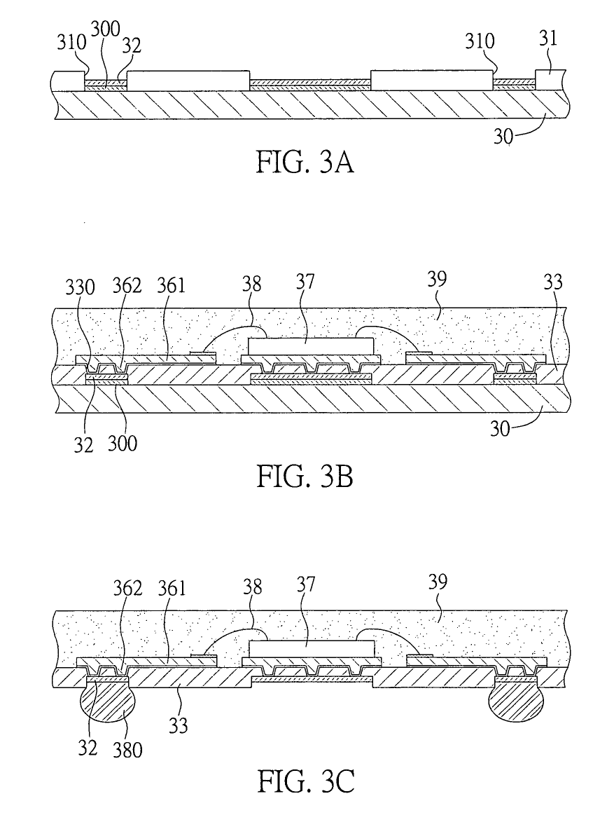

FIGS. 3A to 3C are sectional diagrams showing a semiconductor package and method for fabricating the same according to a second embodiment of the present invention. A main difference between the present embodiment and the first embodiment is an electroplating layer made of a same material as the metal carrier is formed in the openings of the first resist layer before the conductive metal layer is formed in the openings, and when the metal carrier is removed, the electroplating layer is also removed so as to make exposed surface of the conductive metal layer be lower than surface of the dielectric layer.

As shown in FIG. 3A, a first resist layer 31 is formed on a metal carrier 30 (for example a copper plate) and a plurality of openings 310 is formed in the first resist layer 31 to expose the metal carrier 30. Subsequently, an electroplating layer 300 made of the same material (copper) as the metal carrier 30 is formed in the openings 310 by electroplating and then a conductive metal layer 32 is formed on the electroplating layer 300 by electroplating.

As shown in FIG. 3B, the first resist layer 31 is removed and a dielectric layer 33 is formed on the metal carrier 30 having the conductive metal layer 32. A plurality of blind vias 330 is formed in the dielectric layer 33 to expose part of the conductive metal layer 32. Further, conductive circuit 361 is formed on the dielectric layer 33 and conductive posts 362 are formed in the blind vias 330, the conductive circuit 361 being electrically connected to the conductive metal layer 32 through the conductive posts 362. Then, at least one chip 37 is electrically connected to the conductive circuit 361 through bonding wires 38 and an encapsulant 39 is formed to encapsulate the chip 37 and the conductive circuit 361.

As shown in FIG. 3C, the metal carrier 30 and the electroplating layer 300 that are made of the same material are removed by etching, thereby exposing the dielectric layer 33 and the conductive metal layer 32, wherein surface of the conductive metal layer 32 is lower than that of the dielectric layer 33. Conductive elements 380 such as solder balls can be efficiently mounted to the conductive metal layer 32.

### Third Embodiment

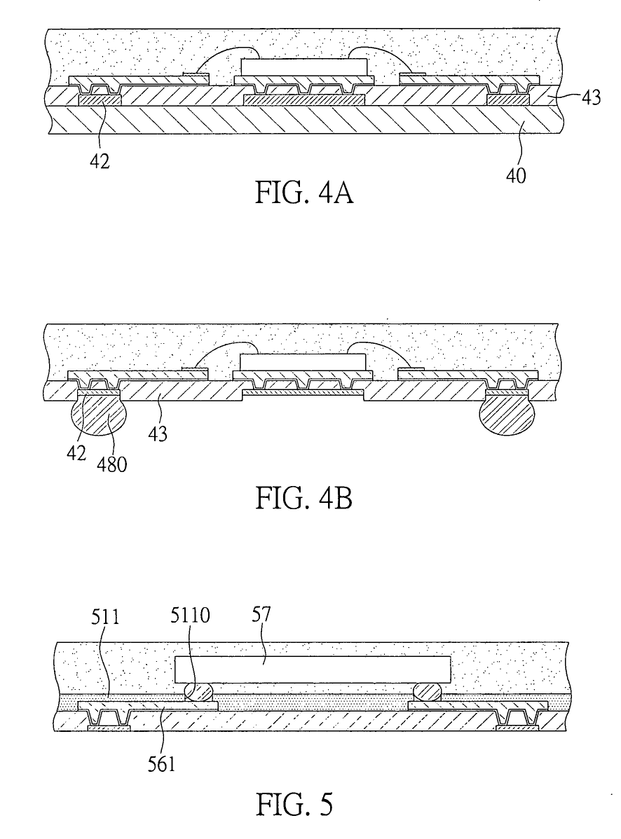

FIGS. 4A and 4B are sectional diagrams showing a semiconductor package and method for fabricating the same according to a third embodiment of the present invention.

A main difference of the present embodiment from the above-described embodiments is the conductive metal layer 42 is made of a same material as the metal carrier 40 such that when the metal carrier 40 is removed by etching, part of the conductive metal layer 42 can also be removed. By controlling etch quantity of the conductive metal layer 42 (approximately 10 μm etch depth), surface of the conductive metal layer 42 can be made to be lower than that of the dielectric layer 43, thereby allowing the conductive elements 480 to be efficiently mounted to the conductive metal layer 42.

### Fourth Embodiment

FIG. 5 is a sectional diagram of a semiconductor package and method for fabricating the same according to a fourth embodiment of the present invention.

A main difference of the present embodiment from the above-described embodiments is an insulative layer 511 such as a solder mask layer is further formed on the conductive circuit 561 and openings 5110 are formed to expose part of the conductive circuit 561 such that the chip 57 can be flip-chip electrically connected to the conductive circuit 561.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A method for fabricating a semiconductor package, comprising the step of:
forming a first resist layer on a metal carrier and forming a plurality of openings in the first resist layer at predefined positions to expose the metal carrier;
forming a conductive metal layer in the openings;
removing the first resist layer, forming a dielectric layer to cover one side of the metal carrier having the conductive metal layer, and forming a plurality of blind vias in the dielectric layer to expose part of the conductive metal layer;
forming conductive circuit on the dielectric layer and forming conductive posts in the blind vias, wherein the conductive circuit is electrically connected to the conductive metal layer through the conductive posts;
electrically connecting at least one chip to the conductive circuit;
forming an encapsulant to encapsulate the chip and the conductive circuit; and
removing the metal carrier so as to expose the dielectric layer and the conductive metal layer.

2. The method of claim 1, wherein the first resist layer is a photo-resist layer, and the openings are formed in the first resist layer by exposure and development.

3. The method of claim 1, wherein the conductive metal layer comprises a die pad corresponding to the chip position and electrical connection terminals for electrically connecting the chip with an external device.

4. The method of claim 1, wherein the conductive metal layer is made of one of Au/Ni/Cu, Ni/Au, Au/Ni/Au, Au/Ni/Pd/Au and Au/Pd/Ni/Pd.

5. The method of claim 1, wherein the dielectric layer is made of a material selected from PP (Prepreg) and ABF (Ajinomoto Build-up Film), and a plurality of blind vias is formed in the dielectric layer by laser processing.

6. The method of claim 1, wherein method for fabricating the conductive circuit and conductive posts comprising:
forming a conductive layer on the dielectric layer and the conductive metal layer exposed from the blind vias through electroless plating;
forming a second resist layer to cover the conductive layer and forming a plurality of patterned openings in the second resist layer;
performing an electroplating process to form conductive circuit on the conductive layer exposed from the openings of the second resist layer and conductive posts in the blind vias, the conductive circuit being electrically connected to the conductive metal layer through the conductive posts; and
removing the second resist layer and the conductive layer covered by the second resist layer.

7. The method of claim 1, wherein a solder material is formed on terminals of the conductive circuit.

8. The method of claim 7, wherein the chip is electrically connected to the solder material on the terminals of the conductive circuit by bonding wires.

9. The method of claim 1, wherein before the conductive metal layer is formed, an electroplating layer made of a same material as the metal carrier is formed in the openings of the first resist layer such that when the metal carrier is removed, the electroplating layer can be removed at the same time, thereby making surface of the conductive metal layer be lower than that of the dielectric layer.

10. The method of claim 1 further comprising mounting conductive elements on the conductive metal layer exposed from the dielectric layer.

11. The method of claim 1, wherein the conductive metal layer is made of a same material as the metal carrier, such that when the metal carrier is removed, part of the conductive metal layer can be removed at the same time, and by controlling the etch quantity of the conductive metal layer, surface of the conductive metal layer can be lower than that of the dielectric layer.

12. The method of claim 1, wherein the conductive circuit is covered by an insulative layer, and openings are formed in the insulative layer to expose part of the conductive circuit such that the chip can be flip-chip electrically connected to the conductive circuit.

13. A semiconductor package, comprising:
a conductive metal layer;
a dielectric layer covering one side of the conductive metal layer, wherein the dielectric layer has blind vias formed to expose part of the conductive metal layer;
conductive circuit formed on the dielectric layer;
conductive posts formed in the blind vias for electrically connecting the conductive circuit with the conductive metal layer;
a chip electrically connected with the conductive circuit; and
an encapsulant encapsulating the chip and the conductive circuit.

14. The semiconductor package of claim 13, wherein the conductive metal layer comprises a die pad corresponding to the chip position and electrical connection terminals for electrically connecting the chip with an external device.

15. The semiconductor package of claim 13, wherein the conductive metal layer is made of one of Au/Ni/Cu, Ni/Au, Au/Ni/Au, Au/Ni/Pd/Au and Au/Pd/Ni/Pd.

16. The semiconductor package of claim 13, wherein the dielectric layer is made of a material selected from PP (Prepreg) and ABF (Ajinomoto Build-up Film), and a plurality of blind vias is formed in the dielectric layer by laser processing.

17. The semiconductor package of claim 13, wherein a solder material is formed on terminals of the conductive circuit.

18. The semiconductor package of claim 17, wherein the chip is electrically connected to the solder material on the terminals of the conductive circuit by bonding wires.

19. The semiconductor package of claim 13, wherein surface of the conductive metal layer is lower than that of the dielectric layer.

20. The semiconductor package of claim 13 further comprising conductive elements mounted on the conductive metal layer exposed from the dielectric layer.

21. The semiconductor package of claim 13, wherein an insulative layer is formed on the conductive circuit and openings are formed in the insulative layer to expose part of the conductive circuit such that the chip can be flip-chip electrically connected with the conductive circuit.

22. The semiconductor package of claim 13, wherein a conductive layer is formed between the conductive circuit and the dielectric layer as well as between the conductive posts and the blind vias.
